(19) United States
(12) Patent Application Publication
(10) Pub. No.: US 2025/0042807 A1
(43) Pub. Date: Feb. 6, 2025

(54) PROCESS FOR FORMING A COATING

(71) Applicant: Pilkington Group Limited, Lathom (GB)

(72) Inventors: Peter Michael HARRIS, Chester Cheshire (GB); Jun NI, Maumee, OH (US); Deborah RAISBECK, Burscough Lancashire (GB); Srikanth VARANASI, Ottawa Hills, OH (US)

(21) Appl. No.: 18/836,779

(22) PCT Filed: Feb. 9, 2023
(86) PCT No.: PCT/GB2023/050298

§ 371 Date: Aug. 8, 2024

Related U.S. Application Data
(60) Provisional application No. 63/308,559, filed on Feb. 10, 2022.

(51) Int. Cl. C03C 17/245

(52) U.S. Cl. CPC C03C 17/245; C03C 2217/228; C03C 2218/1525

(57) ABSTRACT

A chemical vapor deposition process is provided for forming a layer based on manganese oxide over a glass substrate. A gaseous mixture is formed and includes one or more manganese-containing compounds selected from the group consisting of bis(cyclopentadienyl)manganese(II), bis(ethylcyclopentadienyl)manganese (II), (methylcyclopentadienyl)manganese(I) tricarbonyl, and derivatives thereof, and one or more oxygen-containing precursors selected from the group consisting of an organic oxygen-containing compound and molecular oxygen. The gaseous mixture is directed toward and along the glass substrate, and is reacted over the glass substrate to form a manganese oxide coating thereon.

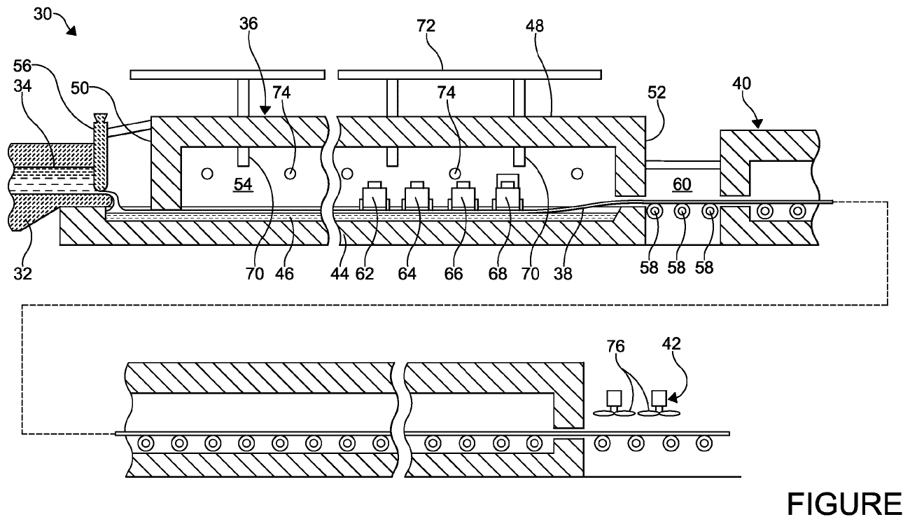

### BACKGROUND

The invention relates in general to a process for forming a coating or layer based on manganese oxide. In particular, the invention relates to a chemical vapor deposition (CVD) process for forming a coating based on manganese oxide over a glass substrate.

### SUMMARY OF THE INVENTION

Embodiments of a chemical vapor deposition process for forming a manganese oxide coating are described below. In an embodiment, the chemical vapor deposition process for forming a manganese oxide coating comprises providing a moving glass substrate. A gaseous mixture comprising a manganese containing compound and an oxygen-containing molecule. The one or more manganese-containing compounds are selected from the group consisting of bis(cyclopentadienyl)manganese(II), bis(ethylcyclopentadienyl)manganese (II), (methylcyclopentadienyl)manganese(I) tricarbonyl, and derivatives thereof, while the one or more oxygen-containing precursors are selected from the group consisting of an organic oxygen-containing compound and molecular oxygen. The gaseous mixture is directed toward and along the glass substrate. The gaseous mixture is reacted over the glass substrate to form a manganese oxide coating over the glass substrate.

In some embodiments, the glass substrate is a glass ribbon in a float glass manufacturing process.

In other embodiments, the manganese oxide coating is formed on a deposition surface of the glass substrate which is at essentially atmospheric pressure.

In some embodiments, a coating apparatus is provided and the gaseous mixture is fed through the coating apparatus before forming the manganese oxide coating over the glass substrate.

The manganese oxide coating may be formed on a deposition surface of the glass substrate which is at essentially atmospheric pressure when the gaseous mixture is reacted to form the manganese oxide coating.

In certain embodiments, the manganese oxide coating forms a continuous layer over the glass substrate. In other embodiments, the manganese oxide coating forms a discontinuous layer over the glass substrate, wherein the manganese oxide covers some areas over the glass substrate and not other areas.

It may be preferred to deposit the manganese oxide coating such that it has a surface concentration of manganese of 0.10 μg/cm² or less.

There may be embodiments wherein the manganese oxide coating is formed over a coating previously formed on the glass substrate. Thus, in some embodiments, the manganese oxide coating is formed over a coating based on silicon oxide previously formed over the glass substrate. In other embodiments, the manganese oxide coating is formed over a coating based on tin oxide previously formed over the glass substrate. The coating based on tin oxide may be undoped or doped, for example, with fluorine.

In certain embodiments, the glass substrate is at a temperature of between 1100° F. (593° C.) and 1400° F. (760° C.) when the manganese oxide coating is formed thereover and the manganese oxide coating is pyrolytic.

In embodiments, an organic oxygen-containing compound is included in the gaseous mixture, and the organic oxygen-containing compound is comprised of one or more carbonyl compounds. In specific embodiments, the organic oxygen-containing compound is an ester, may further be an ester having an alkyl group with a β-hydrogen. The organic oxygen-containing compound may be one or more of ethyl acetate, ethyl formate, ethyl propionate, isopropyl formate, isopropyl acetate, n-butyl acetate and t-butyl acetate. In an especially preferred embodiment, the organic oxygen-containing compound is ethyl acetate.

In some embodiments, the gaseous mixture is comprised of molecular oxygen.

In certain embodiments, the gaseous mixture is comprised of (methylcyclopentadienyl)manganese(I) tricarbonyl or derivatives thereof or both. In a preferred embodiment, the gaseous mixture is comprised of (methylcyclopentadienyl)manganese(I) tricarbonyl.

In a particularly preferred embodiment, the gaseous mixture is comprised of (methylcyclopentadienyl)manganese(I) tricarbonyl and the organic oxygen-containing compound is comprised of ethyl acetate.

### BRIEF DESCRIPTION OF THE DRAWING

The above, as well as other advantages of the process will become readily apparent to those skilled in the art from the following detailed description when considered in the light of the accompanying drawings in which the FIGURE is a schematic view, in vertical section, of an installation for practicing the float glass manufacturing process in accordance with an embodiment of the invention.

### DETAILED DESCRIPTION OF THE INVENTION

It is to be understood that the invention may assume various alternative orientations and step sequences, except where expressly specified to the contrary. It is also to be understood that the specific articles, apparatuses and processes described in the following specification are simply exemplary embodiments of the inventive concepts. Hence, specific dimensions, directions, or other physical characteristics relating to the embodiments disclosed are not to be considered as limiting, unless expressly stated otherwise. Also, although they may not be, like elements in the various embodiments described within this section of the application may be commonly referred to with like reference numerals.

In the context of the present invention, where a layer or coating is said to be “based on” a particular material or materials, this means that the layer or coating predominantly consists of the corresponding said material or materials, which means typically that it comprises at least about 50 at. % of said material or materials.

In the following discussion of the invention, unless stated to the contrary, the disclosure of alternative values for the upper or lower limit of the permitted range of a parameter, coupled with an indication that one of said values is more highly preferred than the other, is to be construed as an implied statement that each intermediate value of said parameter, lying between the more preferred and the less preferred of said alternatives, is itself preferred to said less preferred value and also to each value lying between said less preferred value and said intermediate value.

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention. Typically, when referring to compositions, a composition consisting essentially of a set of components will comprise less than 5% by weight, typically less than 3% by weight, more typically less than 1% by weight of non-specified components.

The term “about” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

The term “consisting of” or “consists of” means including the components specified but excluding other components.

Whenever appropriate, depending upon the context, the use of the term “comprises” or “comprising” may also be taken to include the meaning “consists essentially of” or “consisting essentially of”, and also may also be taken to include the meaning “consists of” or “consisting of”.

References herein such as “in the range x to y” are meant to include the interpretation “from x to y” and so include the values x and y.

In the context of the present invention a transparent material or a transparent substrate is a material or a substrate that is capable of transmitting visible light so that objects or images situated beyond or behind said material can be distinctly seen through said material or substrate.

In the context of the present invention the “thickness” of a layer is, for any given location at a surface of the layer, represented by the distance through the layer, in the direction of the smallest dimension of the layer, from said location at a surface of the layer to a location at an opposing surface of said layer.

In the context of the present invention a “derivative” is a chemical substance related structurally to another chemical substance and theoretically derivable from it.

In an embodiment of the invention, a CVD process for forming a manganese oxide coating (hereinafter also referred to as the “CVD process”) is provided. The CVD process will be described in connection with a coated glass article. Such coated glass articles may have many different applications. For example, and without limitation, the coated glass articles may be utilized in architectural glazings, electronics, and/or have automotive and aerospace applications. They may be used as an absorbing layer in a solar control product or used as a layer of a multi-coating stack design to mimic certain tinted products.

The manganese oxide coating comprises manganese and oxygen. In certain embodiments, the manganese oxide coating may consist essentially of manganese and oxygen. The manganese oxide coating may also include a trace amount of one or more additional constituents such as, for example, carbon. As used herein, the phrase “trace amount” is an amount of a constituent of the layer based on manganese oxide that is less than 0.01 weight %, or equivalently, less than 100 ppm.

In certain embodiments, the manganese oxide coating forms a continuous layer over the glass substrate. However, in other embodiments, the manganese oxide coating forms a discontinuous layer over the glass substrate, wherein the manganese oxide covers some areas over the glass substrate but does not cover other areas over the glass substrate. In certain preferred embodiments, the manganese oxide coating may be deposited over the glass substrate such that it has a surface concentration of manganese of 0.10 μg/cm² or less, more preferably 0.07 μg/cm² or less, even more preferably 0.05 μg/cm² or less.

The CVD process may be carried out in conjunction with the manufacture of the glass substrate. In an embodiment, the glass substrate may be formed utilizing the well-known float glass manufacturing process. An example of a float glass manufacturing process is illustrated in the FIGURE. In this embodiment, the glass substrate may also be referred to as a glass ribbon. However, it should be appreciated that the CVD process can be utilized apart from the float glass manufacturing process or well after formation and cutting of the glass ribbon.

In certain embodiments, the CVD process is a dynamic deposition process. In these embodiments, the glass substrate is moving at the time of forming the manganese oxide coating. Preferably, the glass substrate moves at a predetermined rate of, for example, greater than 3.175 m/min (125 in/min) as the manganese oxide coating is being formed. In an embodiment, the glass substrate is moving at a rate of between 3.175 m/min (125 in/min) and 12.7 m/min (600 in/min) as the manganese oxide coating is being formed.

In certain embodiments, the glass substrate is heated. In an embodiment, the temperature of the glass substrate is about 1100° F. (593° C.) or more when the manganese oxide coating is formed. In another embodiment, the temperature of the glass substrate is between 1100° F. (593° C.) and 1400° F. (760° C.) when the manganese oxide coating is formed thereon.

Preferably, the manganese oxide coating is deposited over the deposition surface of the glass substrate while the surface is at essentially atmospheric pressure. In this embodiment, the CVD process is an atmospheric pressure CVD (APCVD) process.

However, the CVD process is not limited to being an APCVD process as, in other embodiments, the manganese oxide coating may be formed under low-pressure conditions.

The glass substrate is not limited to a particular thickness. Also, the glass substrate may be of a conventional glass composition known in the art. In an embodiment, the glass substrate is a soda-lime-silica glass. In some embodiments, the substrate may be a portion of the float glass ribbon. However, the CVD process is not limited to a soda-lime-silica glass substrate as, in other embodiments, the glass substrate may be a borosilicate or aluminosilicate glass, as examples.

Also, the transparency or absorption characteristics of the glass substrate may vary between embodiments. Further, the color of the glass substrate can vary between embodiments of CVD process. In an embodiment, the glass substrate may be substantially clear. In other embodiments, the glass substrate may be tinted or colored.

The manganese oxide coating may be deposited by providing one or more manganese-containing compounds selected from the group consisting of bis(cyclopentadienyl)manganese(II), bis(ethylcyclopentadienyl)manganese (II), (methylcyclopentadienyl)manganese(I) tricarbonyl, and derivatives thereof, and one or more oxygen-containing precursors selected from the group consisting of an organic oxygen-containing compound and molecular oxygen.

Separate supply lines may extend from the sources of the reactant (precursor) molecules. As used herein, the phrases “reactant molecule” and “precursor molecule” may be used interchangeably to refer to any or all of the manganese-containing compounds and oxygen-containing precursors and/or used to describe the various embodiments thereof disclosed herein. Preferably, the sources of the precursor molecules are provided at a location outside the float bath chamber.

Preferably, the manganese oxide coating is deposited by forming a gaseous mixture. It is preferred that the precursor molecules used to form the gaseous mixture are suitable for use in a CVD process. Such molecules may at some point be a liquid or a solid but are volatile such that they can be vaporized for use in the gaseous mixture. In certain embodiments, the gaseous mixture includes precursor molecules suitable for forming the manganese oxide coating at essentially atmospheric pressure. Once in a gaseous state, the precursor molecules can be included in a gaseous stream and utilized to form the manganese oxide coating.

In some embodiments, the gaseous mixture formed to deposit the manganese oxide coating is comprised of an organic oxygen-containing compound. The organic oxygen-containing compound may be one or more carbonyl compounds. Preferably, the carbonyl compound is an ester. More preferably, the carbonyl compound is an ester having an alkyl group with a β-hydrogen. Alkyl groups with a β-hydrogen containing two to ten carbon atoms are preferred. Preferably, the ester is selected from one or more of ethyl acetate (EtOAc), ethyl formate, ethyl propionate, isopropyl formate, isopropyl acetate, n-butyl acetate and t-butyl acetate. Most preferably, the oxygen-containing compound is ethyl acetate.

In other embodiments of the invention, the gaseous mixture includes molecular oxygen, or molecular oxygen in addition to an organic oxygen-containing compound.

In an embodiment, the manganese-containing compound is comprised of (methylcyclopentadienyl)manganese(I) tricarbonyl or derivatives thereof or both. In a certain preferred embodiment, the manganese-containing compound is comprised of (methylcyclopentadienyl)manganese(I) tricarbonyl and the oxygen-containing precursor is comprised of ethyl acetate. In other embodiments, the gaseous mixture is comprised of molecular oxygen and (methylcyclopentadienyl)manganese(I) tricarbonyl.

The gaseous mixture may also comprise one or more inert gases utilized as carrier or diluent gas. Suitable inert gases include nitrogen (N₂), helium (He), and mixtures thereof. Thus, sources of the one or more inert gases, from which separate supply lines may extend, may be provided.

The precursor molecules are mixed to form the gaseous mixture. In certain embodiments, a coating apparatus may be provided. Preferably, the gaseous mixture is fed through the coating apparatus before forming the manganese oxide coating on the glass substrate. The gaseous mixture may be discharged from the coating apparatus utilizing one or more gas distributor beams. Preferably, the gaseous mixture is formed prior to being fed through the coating apparatus. For example, the precursor molecules may be mixed in a feed line connected to an inlet of the coating apparatus. In other embodiments, the gaseous mixture may be formed within the coating apparatus.

Preferably, the coating apparatus extends transversely across the glass substrate and is provided at a predetermined distance thereabove. The coating apparatus is preferably located at, at least, one predetermined location. When the CVD process is utilized in conjunction with the float glass manufacturing process, the coating apparatus is preferably provided within the float bath section thereof. However, the coating apparatus may be provided in the annealing lehr, and/or in the gap between the float bath and the annealing lehr.

The gaseous mixture is directed toward and along the glass substrate. Utilizing a coating apparatus aids in directing the gaseous mixture toward and along the glass substrate. Preferably, the gaseous mixture is directed toward and along the glass substrate in a laminar flow.

The gaseous mixture reacts at or near the glass substrate to form the manganese oxide coating thereover. In some embodiments, the manganese oxide coating is pyrolytic. As used herein, the term “pyrolytic” may refer to a coating that is chemically bonded to a glass substrate.

The manganese oxide coating of the invention may be formed over one or more previously deposited coatings. For example, the manganese oxide coating may be formed over a previously deposited silicon oxide coating, which was formed over the deposition surface of the glass substrate. The manganese oxide coating may be formed directly on the silicon oxide coating. In other embodiments, the manganese oxide coating may be formed over a previously deposited tin oxide coating, which was formed over the deposition surface of the glass substrate. In these embodiments, the tin oxide coating may be undoped or doped, and where the tin oxide coating is doped, it may be doped with fluorine. The manganese oxide coating may be formed directly on the tin oxide coating.

As discussed above, the manganese oxide coating may be formed in conjunction with the manufacture of the glass substrate in the well-known float glass manufacturing process. The float glass manufacturing process is typically carried out utilizing a float glass installation, such as the installation 30 depicted in the FIGURE. However, it should be understood that the float glass installation 30 described herein is only illustrative of such installations.

As illustrated in the FIGURE, the float glass installation 30 may comprise a canal section 32 along which molten glass 34 is delivered from a melting furnace, to a float bath section 36 where the glass substrate is formed. In this embodiment, the glass substrate will be referred to as a glass ribbon 38. The glass ribbon 38 is a preferable substrate over which the manganese oxide coating is formed. However, it should be appreciated that the glass substrate is not limited to being a glass ribbon.

In embodiments of the invention, the glass ribbon 38 advances from the bath section 36 through an adjacent annealing lehr 40 and a cooling section 42. The float bath section 36 includes: a bottom section 44 within which a bath of molten tin 46 is contained, a roof 48, opposite side walls (not depicted) and end walls 50, 52. The roof 48, side walls and end walls 50, 52 together define an enclosure 54 in which a non-oxidizing atmosphere is maintained to prevent oxidation of the molten tin 46.

In operation, the molten glass 34 flows along the canal 32 beneath a regulating tweel 56 and downwardly onto the surface of the tin bath 46 in controlled amounts. On the molten tin surface, the molten glass 34 spreads laterally under the influence of gravity and surface tension, as well as certain mechanical influences, and it is advanced across the tin bath 46 to form the glass ribbon 38. The glass ribbon 38 is removed from the bath section 36 over lift out rolls 58 and is thereafter conveyed through the annealing lehr 40 and the cooling section 42 on aligned rolls. The deposition of the manganese oxide coating preferably takes place in the float bath section 36, although it may be possible for deposition to take place further along the glass production line, for example, in the gap 60 between the float bath 36 and the annealing lehr 40, or in the annealing lehr 40.

As illustrated in the FIGURE, a coating apparatus 62 is shown within the float bath section 36. The manganese oxide coating may be formed utilizing the coating apparatus 62. In this embodiment, the manganese oxide coating may be formed directly on the glass substrate. In certain embodiments, the manganese oxide coating may be formed over one or more coatings previously formed on the glass ribbon 38. Each of these coatings may be formed utilizing a separate coating apparatus. For example, in an embodiment, a coating layer comprising tin oxide may be deposited utilizing a coating apparatus 62, 64. In this embodiment, the manganese oxide coating may be formed directly on or over the undoped tin oxide coating utilizing another coating apparatus 64-68, which is positioned downstream of the coating apparatus 62, 64 utilized to form the tin oxide coating, provided in the float bath section 36 or in another portion of the float glass installation 30 as described above. In another embodiment, a coating apparatus 66 may be provided and utilized to form a coating that comprises fluorine doped tin oxide. In this embodiment, the manganese oxide coating may be formed directly on or over the doped tin oxide coating utilizing a coating apparatus 68 positioned downstream of the coating apparatus 66.

A suitable non-oxidizing atmosphere, generally nitrogen or a mixture of nitrogen and hydrogen in which nitrogen predominates, is maintained in the float bath section 36 to prevent oxidation of the molten tin 46 comprising the float bath. The atmosphere gas is admitted through conduits 70 operably coupled to a distribution manifold 72. The non-oxidizing gas is introduced at a rate sufficient to compensate for normal losses and maintain a slight positive pressure, on the order of between about 0.001 and about 0.01 atmosphere above ambient atmospheric pressure, so as to prevent infiltration of outside atmosphere. For purposes of the describing the invention, the above-noted pressure range is considered to constitute normal atmospheric pressure.

Preferably, the manganese oxide coating is formed at essentially atmospheric pressure. Thus, the pressure of the float bath section 36, annealing lehr 40, and/or in the gap 60 between the float bath section 36 and the annealing lehr 40 may be essentially atmospheric pressure.

Heat for maintaining the desired temperature regime in the float bath section 36 and the enclosure 54 may be provided by radiant heaters 74 within the enclosure 54. The atmosphere within the lehr 40 is typically atmospheric air, as the cooling section 42 is not enclosed and the glass ribbon 38 is therefore open to the ambient atmosphere. The glass ribbon 38 is subsequently allowed to cool to ambient temperature. To cool the glass ribbon 38, ambient air may be directed against the glass ribbon 38 as by fans 76 in the cooling section 42. Heaters (not depicted) may also be provided within the annealing lehr 40 for causing the temperature of the glass ribbon 38 to be gradually reduced in accordance with a predetermined regime as it is conveyed therethrough.

### Examples

The following examples are presented solely for the purpose of further illustrating and disclosing embodiments of the process for depositing a manganese oxide coating in accordance with the invention, and are not to be construed as a limitation on the invention.

Example 1 shows the deposition of a manganese oxide coating deposited on a lab coater directly on a pyrolytic silicon oxide coating previously formed on a glass substrate. The glass substrate was of the soda-lime-silica variety and was moving at the time the manganese oxide coating was deposited thereon at a line speed of 100 in./min. The manganese oxide coating was deposited by forming a gaseous mixture of bis(cyclopentadienyl)manganese(II) and ethyl acetate. The flow rates were 0.90 standard liters per minute (“slpm”) for the bis(cyclopentadienyl)manganese(II) and 0.94 slpm for the ethyl acetate. These precursor molecules were mixed to form a gaseous mixture and then fed through the lab coating apparatus before being directed toward and along the glass substrate. The estimated gas phase concentrations were 0.50% for the bis(cyclopentadienyl)manganese(II) and 1.45% for the ethyl acetate, with the balance being nitrogen. A uniform coating of manganese oxide was formed over the glass substrate at a deposition rate of 44 Å/sec., the coating having a thickness determined by optical modelling of 400 Å.

Examples 2-4 show the deposition of a manganese oxide coating deposited on a lab coater directly on a pyrolytic tin oxide coating previously formed on a glass substrate. In each of examples 2-4, the glass substrate was of the soda-lime-silica variety and was moving at the time the manganese oxide coating was deposited thereon at a line speed of 200 in./min. The manganese oxide coating was deposited by forming a gaseous mixture of bis(cyclopentadienyl)manganese(II) and ethyl acetate. The flow rates for these precursors were as follows: ex. 2-0.10 slpm bis(cyclopentadienyl)manganese(II) and 0.12 slpm ethyl acetate, ex. 3-0.20 slpm bis(cyclopentadienyl)manganese(II) and 0.23 slpm ethyl acetate, and ex. 4-0.30 slpm bis(cyclopentadienyl)manganese(II) and 0.35 slpm ethyl acetate. The precursor molecules were mixed to form a gaseous mixture and then fed through the lab coating apparatus before being directed toward and along the glass substrate. The estimated gas phase concentrations were as follows: ex. 2-0.06% bis(cyclopentadienyl)manganese(II) and 0.18% ethyl acetate, ex. 3-0.12% bis(cyclopentadienyl)manganese(II) and 0.35% ethyl acetate, and ex. 4-0.18% bis(cyclopentadienyl)manganese(II) and 0.54% ethyl acetate. In each case, the balance was nitrogen. The manganese oxide coatings of examples 2-4 were discontinuous coatings, with manganese oxide covering some areas of the glass substrate and not others. The surface concentration of manganese was measured for each of examples 2-4 using inductively coupled plasma—optical emission spectrometry (“ICP-OES”) at 0.35 μg/cm² for ex. 2, 1.60 μg/cm² for ex. 3, and 2.30 μg/cm² for ex. 4.

Examples 5-7 show the deposition of a manganese oxide coating deposited on a lab coater directly on a pyrolytic tin oxide coating previously formed on a glass substrate. In each of examples 5-7, the glass substrate was of the soda-lime-silica variety and was moving at the time the manganese oxide coating was deposited thereon at a line speed of 47 in./min. The manganese oxide coating was deposited by forming a gaseous mixture of (methylcyclopentadienyl)manganese(I) tricarbonyl and molecular oxygen (O₂). The flow rates for these precursors were as follows: ex. 5-0.75 slpm (methylcyclopentadienyl)manganese(I) tricarbonyl and 0.50 slpm O₂, ex. 6-1.00 slpm (methylcyclopentadienyl)manganese(I) tricarbonyl and 0.50 slpm O₂, and ex. 7-0.50 slpm (methylcyclopentadienyl)manganese(I) tricarbonyl and 0.50 slpm O₂. The precursor molecules were mixed to form a gaseous mixture and then fed through the lab coating apparatus before being directed toward and along the glass substrate. The estimated gas phase concentrations were as follows: ex. 5-0.79% (methylcyclopentadienyl)manganese(I) tricarbonyl and 2.10% O₂, ex. 6-1.06% (methylcyclopentadienyl)manganese(I) tricarbonyl and 2.10% O₂, and ex. 7-0.53% (methylcyclopentadienyl)manganese(I) tricarbonyl and 2.10% O₂, the balance being nitrogen. The manganese oxide coatings of examples 5-7 were discontinuous coatings, with manganese oxide covering some areas of the glass substrate and not others. The manganese oxide coverage was measured for each of examples 5-7 using X-ray Photoelectron Spectroscopy (XPS) at 73.0% for ex. 5, 83.6% for ex. 6, and 63.5% for ex. 7.

Examples 8-10 show the deposition of a manganese oxide coating deposited where the glass substrate was of the soda-lime-silica variety, formed in conjunction with a float glass manufacturing process, and was moving at a line speed of 472 in./min when the coating layers were deposited in the heated zone of the float glass manufacturing process. A pyrolytic tin oxide coating was deposited over the glass substrate and the manganese coating was deposited on the tin oxide coating. The manganese oxide coating was deposited by forming a gaseous mixture of (methylcyclopentadienyl)manganese(I) tricarbonyl and ethyl acetate. The flow rates for these precursors were as follows: ex. 8-3.5 cc/min. (methylcyclopentadienyl)manganese(I) tricarbonyl and 17.6 cc/min. ethyl acetate, ex. 9-2.5 cc/min. (methylcyclopentadienyl)manganese(I) tricarbonyl and 17.6 cc/min. ethyl acetate, and ex. 10-1.0 cc/min. (methylcyclopentadienyl)manganese(I) tricarbonyl and 17.6 cc/min. ethyl acetate. The precursor molecules were mixed to form a gaseous mixture and then fed through the coating apparatus before being directed toward and along the glass ribbon. The estimated gas phase concentrations were as follows: ex. 8-0.11% (methylcyclopentadienyl)manganese(I) tricarbonyl and 0.88% ethyl acetate, ex. 9-0.08% (methylcyclopentadienyl)manganese(I) tricarbonyl and 0.88% ethyl acetate, and ex. 10-0.03% (methylcyclopentadienyl)manganese(I) tricarbonyl and 0.88% ethyl acetate, the balance being nitrogen. The manganese oxide coatings of examples 8-10 were discontinuous coatings, with manganese oxide covering some areas of the glass substrate and not others. The surface concentration of manganese was measured for each of examples 8-10 using ICP-OES at 0.58 μg/cm² for ex. 8, 0.25 μg/cm² for ex. 9, and 0.10 μg/cm² for ex. 10.

The foregoing description is considered as illustrative only of the principles of the invention. Further, since numerous modifications and changes will readily occur to those skilled in the art, it is not desired to limit the invention to the exact construction and processes shown and described herein. Accordingly, all suitable modifications and equivalents may be considered as falling within the scope of the invention.

1.-21. (canceled)

22. A chemical vapor deposition process for forming a manganese oxide coating over a glass substrate, comprising:
providing a glass substrate;
forming a gaseous mixture comprised of one or more manganese-containing compounds selected from the group consisting of bis(cyclopentadienyl)manganese(II), bis(ethylcyclopentadienyl)manganese (II), (methylcyclopentadienyl)manganese(I) tricarbonyl, and derivatives thereof, and one or more oxygen-containing precursors selected from the group consisting of an organic oxygen-containing compound and molecular oxygen;
directing the gaseous mixture toward and along the glass substrate; and
reacting the gaseous mixture over the glass substrate to form a coating of manganese oxide over the glass substrate.

23. The chemical vapor deposition process defined in claim 22, wherein the glass substrate is a glass ribbon in a float glass manufacturing process.

24. The chemical vapor deposition process defined in claim 22, further comprising providing a coating apparatus and feeding the gaseous mixture through the coating apparatus before forming the manganese oxide coating over the glass substrate.

25. The chemical vapor deposition process defined in claim 22, wherein the manganese oxide coating is formed on a deposition surface of the glass substrate which is at essentially atmospheric pressure when the gaseous mixture is reacted to form the manganese oxide coating.

26. The chemical vapor deposition process defined in claim 22, wherein the manganese oxide coating forms a continuous coating layer over the glass substrate.

27. The chemical vapor deposition process defined in claim 22, wherein the manganese oxide coating forms a discontinuous coating layer over the glass substrate.

28. The chemical vapor deposition process defined in claim 22, wherein the manganese oxide coating has a surface concentration of manganese of 0.10 μg/cm² or less.

29. The chemical vapor deposition process defined in claim 22, wherein the manganese oxide coating is formed over a coating previously formed on the glass substrate.

30. The chemical vapor deposition process defined in claim 22, wherein the manganese oxide coating is formed over a coating based on silicon oxide previously formed over the glass substrate.

31. The chemical vapor deposition process defined in claim 22, wherein the manganese oxide coating is formed over a coating based on tin oxide previously formed over the glass substrate.

32. The chemical vapor deposition process defined in claim 31, wherein the coating based on tin oxide is doped with fluorine.

33. The chemical vapor deposition process defined in claim 22, wherein the glass substrate is at a temperature of between 1100° F. (593° C.) and 1400° F. (760° C.) when the manganese oxide coating is formed thereover.

34. The chemical vapor deposition process defined by claim 22, wherein the manganese oxide coating is pyrolytic.

35. The chemical vapor deposition process defined by claim 22, wherein an organic oxygen-containing compound is included in the gaseous mixture, and the organic oxygen-containing compound is comprised of one or more carbonyl compounds.

36. The chemical vapor deposition process defined by claim 35, wherein the organic oxygen-containing compound is an ester.

37. The chemical vapor deposition process defined by claim 36, wherein the organic oxygen-containing compound is an ester having an alkyl group with a β-hydrogen.

38. The chemical vapor deposition process defined by claim 35, wherein the organic oxygen-containing compound is one or more of ethyl acetate, ethyl formate, ethyl propionate, isopropyl formate, isopropyl acetate, n-butyl acetate and t-butyl acetate.

39. The chemical vapor deposition process defined by claim 35, wherein the organic oxygen-containing compound is ethyl acetate.

40. The chemical vapor deposition process defined by claim 22, wherein the gaseous mixture is comprised of molecular oxygen.

41. The chemical vapor deposition process defined by claim 22, wherein the gaseous mixture is comprised of (methylcyclopentadienyl)manganese(I) tricarbonyl or derivatives thereof or both.

42. The chemical vapor deposition process defined by claim 22, wherein the gaseous mixture is comprised of (methylcyclopentadienyl)manganese(I) tricarbonyl.
